(19) United States
(12) Patent Application Publication
(10) Pub. No.: US 2025/0218778 A1
(43) Pub. Date: Jul. 3, 2025

(54) METHODS AND APPARATUS TO MODIFY CARBIDE SURFACES IN SEMICONDUCTOR DEVICE FABRICATION PROCESSES

(71) Applicant: Intel Corporation, Santa Clara, CA (US)

(72) Inventors: Robert Stanley Jordan, Portland, OR (US); James Munro Blackwell, Portland, OR (US); Brandon Jay Holybee, Portland, OR (US); Blake Matthew Bluestein, Hillsboro, OR (US); Eric Charles Mattson, Portland, OR (US)

(21) Appl. No.: 18/397,719

(22) Filed: Dec. 27, 2023

(51) Int. Cl. H01L 21/228; H01L 21/02; H01L 21/027

(52) U.S. Cl. CPC H01L 21/228; H01L 21/02529; H01L 21/0271

(57) ABSTRACT

Systems, apparatus, articles of manufacture, and methods to modify carbide surfaces in semiconductor device fabrication processes are disclosed. An example apparatus includes a semiconductor substrate; a layer of carbide on the substrate; and a surface treatment covalently bonded to a surface of the carbide, the surface treatment including at least one of nitrogen or carbon.

### FIELD OF THE DISCLOSURE

This disclosure relates generally to semiconductor devices and, more particularly, to methods and apparatus to modify carbide surfaces in semiconductor device fabrication processes.

### BACKGROUND

Semiconductor device fabrication involves a series of processes in which successive layers of materials are deposited or epitaxially grown on a semiconductor wafer to build up structural features defining components in a semiconductor device (e.g., transistors and/or other electrical components). The size, spacing, and/or shape of such structural features is often achieved by selectively controlling (e.g., via photolithographically patterning) where additional layer(s) of material are added to the underlying wafer (and any previously deposited layers of material) and/or selectively controlling (e.g., via photolithographically patterning) where portions of layer(s) of material already deposited on the underlying wafer are removed (e.g., via an etching process).

### BRIEF DESCRIPTION OF THE DRAWINGS

FIG. 1 illustrates different types of common grafting chemistries being applied to surfaces of silicon oxide, silicon nitride, and silicon carbide.

FIG. 2 illustrates different example types of reactive intermediates or molecules that can be grafted onto the surface of silicon carbide.

FIG. 3 illustrates a specific example experimental process to surface graft a nitrene intermediate (e.g., a nitrene) onto a layer (e.g., blanket) of silicon carbide.

FIG. 4 illustrates an example aryl azide to provide a surface coating for silicon carbide in accordance with teachings disclosed herein.

FIG. 5 illustrates another example aryl azide that includes a polymer chain that may be attached to silicon carbide in accordance with teachings disclosed herein.

FIG. 6 illustrates an example two-stage process to modify the surface of silicon carbide with a functional handle that is further modified through a derivatization process.

FIG. 7 is a flowchart representative of an example method that may be performed to modify or treat a carbide surface through a surface grafting process in accordance with teachings disclosed herein.

FIGS. 8-12 illustrate example stages in a lithographic process implemented in accordance with teachings disclosed herein.

FIGS. 13-15 illustrate example stages in an ASD process implemented in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Surface grafting of reactive molecules is a common process used for the tailoring of the surface properties of materials through the covalent attachment of molecules to reactive functional groups already on the surface of the underlying material to be treated. Within semiconductor manufacturing, surface grafting is an important component in the implementation of directed self-assembly (DSA) and area-selective deposition (ASD) technologies. Common grafting molecules include self-assembled monolayers (SAMs) and organic coatings.

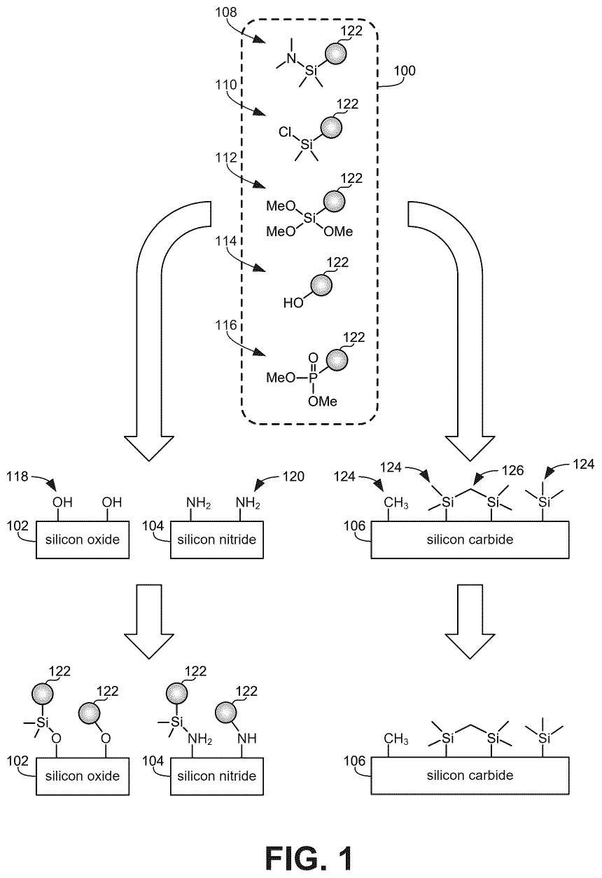

Existing surface grafting strategies require reactive functional groups (e.g., a hydroxyl group (—OH), an amino group (NH₂), etc.) to be present on the material surface to be treated. These reactive functional groups are needed to facilitate the grafting chemistry. In particular, such known reactive functional groups provide the locations for the formation of covalent bonds with the molecules that are to be grafted onto the material surface. As a result, existing surface grafting strategies are limited to certain types of underlying materials, such as silicon oxide and silicon nitride. By contrast, many carbides (e.g., silicon carbide) do not include any of the reactive groups relied on to enable surface grafting using existing technologies. As a result, carbides are unreactive to known grafting strategies as represented in FIG. 1.

FIG. 1 illustrates different types of known grafting chemistries 100 being applied to surfaces of silicon oxide 102, silicon nitride 104, and silicon carbide 106. The grafting chemistries 100 shown in FIG. 1 include silyl amides 108, silyl chlorides 110, trialkoxy silanes 112, alcohols 114, and phosphonates 116. For these chemistries 100 to attach to and, thus, modify the surfaces of the silicon oxide 102, silicon nitride 104, and silicon carbide 106, the surfaces need to have suitably reactive functional groups. As shown in FIG. 1, the silicon oxide 102 includes hydroxyl groups 118 on the surface. Since the hydroxyl groups 118 are reactive, the grafting chemistries 100 are able to covalently bond with the surface of the silicon oxide 102 as shown at the bottom of FIG. 1. Likewise, the silicon nitride 104 includes amino groups 120 on the surface. Since the amino groups 120 are reactive, the grafting chemistries 100 are able to covalently bond with the surface of the silicon nitride 104 as shown at the bottom of FIG. 1. The particular way in which the surfaces of the silicon oxide 102 and/or the silicon nitride 104 are modified by the grafting chemistries 100 depends upon the chemical nature of the displayed surface functional group(s) (generically represented by a circle 122 in the different chemistries 100 of FIG. 1) and the choice of the grafting chemistries 100. Many different surface functional group(s) 122 can be used to achieve different surface modifications. For instance, some surface functional group(s) 122 facilitate the formation of a surface coating on the underlying material (e.g., the silicon oxide 102 or the silicon nitride 104). Some surface functional group(s) 122 facilitate polymer grafting onto the underlying material. Some surface functional group(s) 122 serve to modify the surface energy and/or wetting properties of the surface of the underlying material (e.g., to make the surface more hydrophobic or more hydrophilic).

Unlike silicon oxide 102 and silicon nitride 104, silicon carbide 106 does not include a reactive functional group on its surface. Rather, as shown on the right side of FIG. 1, the surface of the silicon carbide 106 includes methyl groups (CH₃) 124 (one of which is explicitly labelled (at the left end of the silicon carbide 106 in FIG. 1) with all other methyl groups 124 identified by the single bond lines with an unlabeled end) bonded to silicon. Additionally or alternatively, the surface of silicon carbide 106 can include methylene groups (CH₂) 126 (indicated by an unlabeled corner between two bond lines) bonded to two silicon atoms. Neither methyl groups 124 nor methylene groups 126 are reactive functional groups. As a result, as shown in FIG. 1, there is no reaction between the silicon carbide 106 and the grafting chemistries 100. Therefore, existing grafting technologies are ineffective to modify silicon carbide (or other carbides).

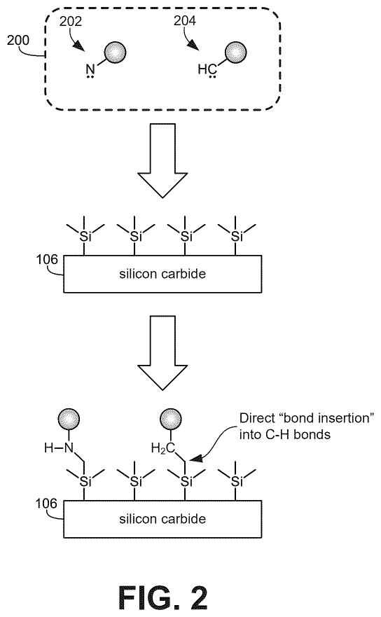

Examples disclosed herein enable surface treatments or surface modifications to carbide materials (e.g., silicon carbide) through surface grafting of highly reactive intermediates (e.g., reactive molecules) that can covalently bond with and, thus, modify traditionally unreactive carbide surfaces. FIG. 2 illustrates different example types of reactive intermediates or molecules 200 that can be grafted onto the surface of silicon carbide 106. As shown in the illustrated example, the reactive molecules 200 includes nitrene intermediates (e.g., nitrenes) 202 and carbene intermediates (e.g., carbenes) 204. Both nitrenes 202 and carbenes 204 are highly reactive intermediates that can undergo diverse reactions, including insertion reactions into carbon-hydrogen (C—H) bonds. As such, while the C—H bonds on the surface of silicon carbide 106 are unreactive, experimental testing has shown that the formation of nitrene and/or carbene intermediates 202, 204 at the surface of silicon carbide 206 can affect a C—H insertion reaction by which a direct covalent modification of the surface is achieved. That is, examples disclosed herein enable the direct modification of silicon carbide through surface grafting without surface pre-functionalization through oxidation to create grafting sites.

As shown in the illustrated example of FIG. 2, the surface of the silicon carbide 106 terminates with C—H bonds (represented by the unlabeled free ends of the lines extending outward from the silicon (Si) atoms). Specifically, in FIG. 2, the surface of the silicon carbide 106 is defined by silicon atoms bonded to three methyl groups (e.g., a carbon atom bonded to three hydrogen atoms). When a nitrene 202 and/or a carbene 204 is introduced to the surface of the silicon carbide 106, the intermediate is inserted between one C—H bond in what was previously a methyl group. That is, the nitrogen (from the nitrene 202) or the carbon (from the carbene 204) covalently bonds directly with the carbon in the methyl group (in place of one of the hydrogen atoms) and the displaced hydrogen atom covalently bonds with the nitrogen or carbon of the inserted intermediate reactive molecule (e.g., the nitrene 202 or the carbene 204).

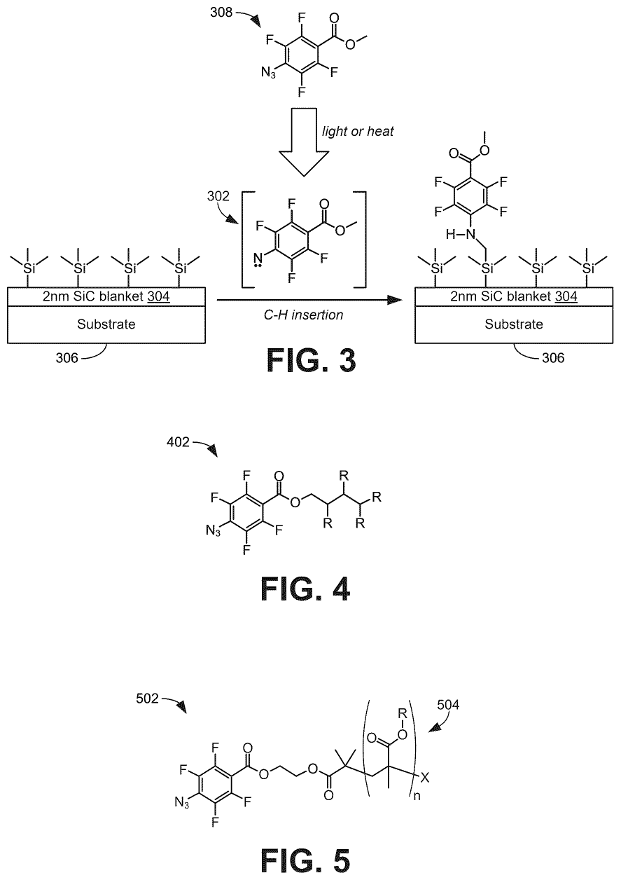

FIG. 3 illustrates a specific example process to surface graft a nitrene intermediate 302 (e.g., a nitrene) onto a layer of silicon carbide 304. In this example, approximately 2 nanometers (nm) of silicon carbide 304 is on an underlying substrate 306. The underlying substrate 306 can be any suitable material (e.g., a semiconductor (silicon) wafer). As represented in the illustrated example, the nitrene intermediate 302 is generated from the decomposition of an aryl azide 308. This decomposition can be activated with either heat or light. More particularly, in some experimental examples, a solution containing the aryl azide 308 is spin coated onto the silicon carbide 304 and then heated through a bake procedure to generate the nitrene intermediate 302 at the surface of the silicon carbide 304 for surface grafting. In other examples, a solution containing the aryl azide 308 is applied via drop casting onto the silicon carbide 304 (and underlying substrate 306) that had already been heated to generate the nitrene intermediate 302 at the surface of the silicon carbide 304 for surface grafting. In other examples, a solution containing the aryl azide 308 is spin coated onto the silicon carbide 304 followed by an ultraviolet (UV) exposure process within a nitrogen gas (N₂) atmosphere to generate the nitrene intermediate 302 at the surface of the silicon carbide 304 for surface grafting. A rinse with propylene glycol methyl ether acetate (PGMEA) post attempted grafting removes any remaining physiosorbed molecules.

Analysis of the resulting surfaces of the silicon carbide 304 associated with the different samples based on contact angle (CA) measurements using both water and diiodomethane are shown in Table 1 below. As outlined, the results show some change in the contact angle measurements relative to an untreated silicon carbide surface, thereby indicating that surface modifications occurred. Among the different experimental examples, UV activation resulted in the greatest change in contact angle, though the heat-based activation approaches also resulted in at least some change in the surface conditions of the silicon carbide 304 due to the grafting.

TABLE 1
Contact angles on 2 nm SiC blanket film based
on surface grafting using aryl azide

| | Water contact | Diiodomethane |
|---|---|---|
| Conditions | angle | contact angle |
| N/A - unmodified SiC | 84 | 46 |
| Spin coat + 180 C. 60 s | 83 | 44 |
| Drop cast on hot substrate @ 120 C. | 82 | 43 |
| Spin coat + UV 3 min | 74 | 37 |

In addition to the contact angle measurements, the above-noted samples were analyzed using x-ray photoelectron spectroscopy (XPS), Fourier transform infrared (FTIR) spectroscopy, and time of flight secondary ion mass spectrometry (TOFSIMS) to help confirm the surface modifications are based on covalent surface modification (e.g., C—H insertion). These inspection processes confirmed that surface grafting based on C—H insertion took place using all three activation techniques (with the greatest effects occurring with the UV activation process).

In some examples, the particular functional groups included in the nitrene and/or carbene intermediates used for surface grafting can result in many different surface treatments or modifications. For instance, FIG. 4 illustrates an example aryl azide 402 to provide a surface coating for silicon carbide in accordance with teachings disclosed herein. Other nitrenes and/or carbenes may additionally or alternatively be used to facilitate surface coatings of silicon carbide. FIG. 5 illustrates another example aryl azide 502 that includes a polymer chain 504 that may be attached to silicon carbide in accordance with teachings disclosed herein. Other nitrenes and/or carbenes may additionally or alternatively be used to facilitate the attachment of polymers onto silicon carbide.

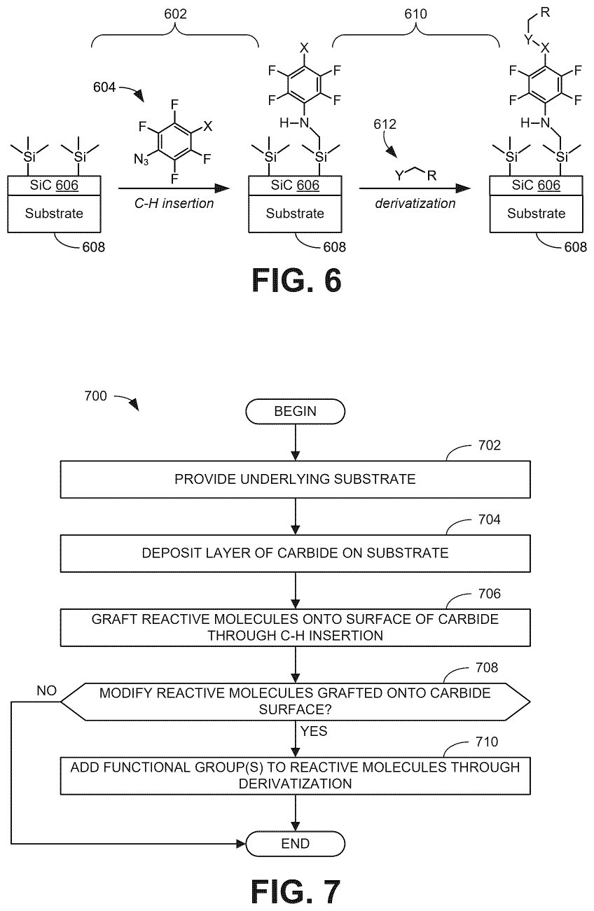

Further, in some examples, nitrenes and/or carbenes can serve as a functional handle to add any other suitable functional groups with other desired properties through subsequent processing. More particularly, in some examples, the treatment of silicon carbide can be a multiple (e.g., two) stage process in which a nitrene and/or carbene intermediate is surface grafted onto the silicon carbide through C—H insertion followed by a subsequent derivatization process. This two-stage process is represented in FIG. 6. Specifically, FIG. 6 illustrates a first stage 602 including the surface grafting of a nitrene 604 onto a layer of silicon carbide 606 on an underlying substrate 608. In this example, the nitrene 604 is an aryl azide. Thus, the first stage 602 of FIG. 6 is similar to the surface grafting process detailed in connection with FIG. 3. The illustrated example of FIG. 6 further shows a second stage 610 corresponding to a derivatization process in which a functional group 612 is attached to the nitrene molecule that was added (e.g., inserted) onto the surface of the silicon carbide 606. Thus, the nitrene molecule serves as a functional handle for other functional groups that may subsequently be added.

While the foregoing examples have been described with respect to the use of aryl azides as the source for the nitrene intermediates, in other examples, surface grafting based on C—H insertion can be achieved using other types of nitrene intermediates (e.g., other than from aryl azides). For instance, other example nitrene intermediates can be obtained from alkyl or aryl isocyanates Furthermore, similar approaches can be used to surface graft carbene intermediates onto silicon carbide in accordance with teachings disclosed herein. In some examples, carbene intermediates can be obtained from diazo-compounds. Further, while the above examples are discussed with reference to the surface treatment of silicon carbide, teachings disclosed herein can be applied to other types of carbides that include C—H bonds at the surface of such materials. For instance, other example carbides include boron carbide and tungsten carbide.

FIG. 7 is a flowchart representative of an example method 700 that may be performed to modify or treat a carbide (e.g., silicon carbide) surface through a surface grafting process. In some examples, some or all of the operations outlined in the example method of FIG. 7 are performed automatically by equipment that is programmed to perform the operations. Although the example method is described with reference to the flowchart illustrated in FIG. 7, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

The example method 700 of FIG. 7 begins at block 702 by providing an underlying substrate. In some examples, the underlying substrate is a semiconductor wafer. In some such examples, the underlying substrate may have gone through any suitable number of fabrication processes prior to the beginning of the method 700 of FIG. 7. The underlying substrate noted in block 702 of FIG. 7 may correspond to any one of the substrates 306, 608 of FIGS. 3 and/or 6. At block 704, a layer of carbide is deposited on the substrate. The layer of carbide noted in block 704 of FIG. 7 may correspond to any one of the layers of silicon carbide 106, 304, 606 of FIGS. 1-3 and/or 6. In other examples, the layer of carbide noted in block 704 may correspond to a different type of carbide.

At block 706, reactive molecules are grafted onto the surface of the carbide through C—H insertion. More particularly, in some examples, the reactive molecules include nitrene and/or carbene intermediates. In some examples, the reactive nitrene and/or carbene intermediates are produced for grafting by decomposing a solution containing the molecules that has been deposited onto the surface of the carbide (e.g., via spin coating, drop casting, etc.). In some such examples, the decomposition is achieved through heat activation and/or light activation. Additionally or alternatively, in some examples, the reactive molecules can be provided to the surface of the carbide for grafting in the vapor phase through a vapor deposition process (e.g., chemical vapor deposition).

At block 708, the example process determines whether to modify the reactive molecules grafted onto the carbide surface. That is, in some examples, the reactive molecules may serve as a functional handle for additional chemistries to be added during subsequent derivatization. Thus, if further modifications to the reactive molecules are to be implemented, control advances to block 710 where one or more functional group(s) are added to the reactive molecules through derivatization. Thereafter, the example method 700 of FIG. 7 ends. If, at block 708, it is determined that no further modifications are needed, the example method 700 of FIG. 7 ends.

There are many possible uses for surface treatments of carbides in the semiconductor manufacturing context that may be implemented in accordance with teachings disclosed herein. For example, silicon carbide is often used as an underlayer in extreme UV (EUV) lithography. As such, being able to modify the surface properties of silicon carbide can improve the efficiency and/or effectiveness of EUV lithography processes. For example, many EUV photoresists are chemically amplified resists that leave a residue after EUV exposure and the development (e.g., removal) of the exposed regions of the resist. This residue is often removed through additional aggressive plasma-based material removal processes that can degrade the unexposed regions of the resist. This challenge results from the fact that the underlayer needs to provide good adhesion with the photoresist when initially applied for reliable patterning of the photoresist. However, this strong adhesion makes it difficult to remove the unwanted (e.g., exposed) portions of the resist through the development process. In accordance with teachings disclosed herein, a silicon carbide underlayer can be surface treated with molecules that provide dynamic properties that change throughout the lithographic process to avoid these challenges. Specifically, the reactive molecules grafted onto the surface of the silicon carbide underlayer can be selected to provide good adhesion with the photoresist prior to exposure. However, after EUV exposure, the reactive molecules grafted onto the surface of the underlaying can change properties to reduce their adhesiveness with the photoresist (e.g., changes from being resist-philic to being resist-phobic) so that the resist can be more easily removed during development without the need for aggressive removal processes. In some examples, the change in surface property (e.g., from resist-philic to resist-phobic) can be triggered or activated by light (e.g., the EUV patterning exposure or subsequent light exposure), heat, and/or the introduction of a chemical catalyst.

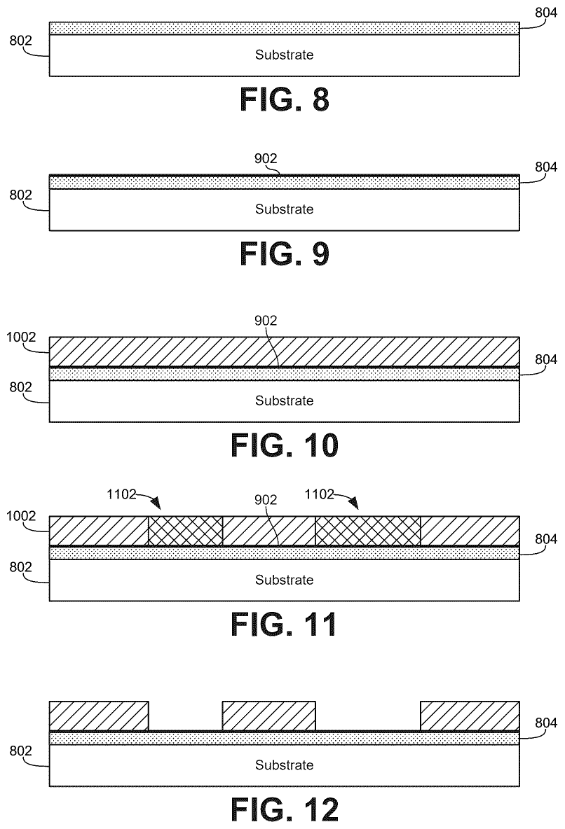

FIGS. 8-12 illustrate example stages in a lithographic process implemented in accordance with teachings disclosed herein. FIG. 8 illustrates an example underlying substrate 802 (e.g., a semiconductor wafer) onto which a layer of silicon carbide 804 has been added. FIG. 9 illustrates the silicon carbide 804 after surface treatment to produce a surface treatment 902 that includes reactive molecules grafted onto the silicon carbide through C—H insertion as discussed above. FIG. 10 illustrates an example photoresist 1002 deposited onto the silicon carbide 804. As discussed above, adhesion of the photoresist 1002 onto the silicon carbide 804 is facilitated by the properties of the reactive molecules included in the surface treatment 902. FIG. 11 illustrates the results of EUV exposure to certain portions 1102 defined by a corresponding EUV photomask. As represented, the EUV exposure results in a change in the photoresist 1002 so that the exposed portions 1102 are dissolvable by a development solution. FIG. 12 illustrates the resulting assembly after a development process that removes the exposed portions 1102 of the photoresist 1002. In this example, before the development process and after the stage of manufacture represented in FIG. 11, the assembly undergoes a heat treatment to activate a change in the reactive molecules included in the surface treatment 902 of the silicon carbide 804. More particularly, in this example, the heat treatment reduces the adhesive properties of the silicon carbide with respect to the photoresist 1002 so that the exposed portions 1102 can be easily removed with little or no residue. In this manner, the need for an aggressive plasma-based removal process may be avoided, thereby avoiding any resulting degradation to the unexposed portions of the photoresists 1002.

Another example beneficial use for teachings disclosed herein is in the context of area-selective deposition (ASD). ASD involves selectively modifying the properties of different portions or areas of a surface of material in different ways so that the different portions or areas of the material react in different ways with other materials. For instance, a first portion of a surface of a substrate material (e.g., a silicon carbide) can resist adhesion with a second material while a second portion of the surface of the substrate material can promote adhesion with the second material. In such scenarios, when the second material is deposited on the substrate material, the second material will primarily (if not exclusively) attach or adhere to the second portion of the substrate material while remaining spaced apart from the first portion of the substrate material. Thus, ASD can be employed to deposit materials on selective locations of a surface without the need for the multiple stages and associated challenges of lithographic patterning.

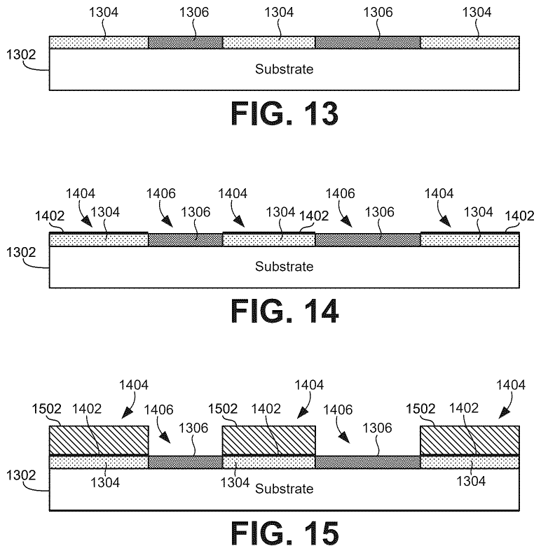

FIGS. 13-15 illustrate example stages in an ASD process implemented in accordance with teachings disclosed herein. FIG. 13 illustrates an example underlying substrate 1302 (e.g., a semiconductor wafer) onto which a pattern of silicon carbide 1304 has been added between regions of a different material 1306. In this example, the different material 1306 is copper with the alternating regions of different materials defining a grating of silicon carbide and copper. FIG. 14 illustrates the surface materials (e.g., the silicon carbide 1304 and the different material 1306) after surface treatment to produce a surface treatment 1402 that includes reactive molecules grafted onto the silicon carbide through C—H insertion as discussed above. As shown, while the surface treatment 1402 attached to the silicon carbide 1304, the surface treatment 1402 does not attach to the different material 1306 (e.g., copper in this example) because there are no C—H bonds in the different material 1306 to enable the C—H insertion. Thus, in this example, selective first areas 1404 (corresponding to the silicon carbide 1304) are modified while second areas 1406 (corresponding to the different material 1306) remain untreated. FIG. 15 illustrates an example mask material 1502 deposited onto the silicon carbide 1304. In this example, the mask material 1502 is selected to not adhere with the different material 1306 associated with the untreated second areas 1406. However, in this example, the reactive molecules included in the surface treatment 1402 of the first areas 1404 include functional groups that promote or facilitate adhesion with the mask material 1502. Accordingly, as shown in FIG. 15, the mask material 1502 attaches to the silicon carbide 1304 at the first areas 1404 but not the second areas 1406.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that enable the direct modifications of carbide through surface grafting without needing to go through pre-functionalization processes of oxidation to generate graft sites. This has potential advantages in many different applications within the semiconductor device manufacturing context including improvements to EUV lithography and the potential to apply area-selective deposition to carbide surfaces.

Further examples and combinations thereof include the following:

Example 1 includes an apparatus comprising a semiconductor substrate, a layer of carbide on the substrate, and a surface treatment covalently bonded to a surface of the carbide, the surface treatment including at least one of nitrogen or carbon.

Example 2 includes the apparatus of example 1, wherein the carbide is silicon carbide.

Example 3 includes the apparatus of any one examples 1 or 2, wherein the surface treatment includes a nitrene.

Example 4 includes the apparatus of any one examples 1-3, wherein the surface treatment includes a carbene.

Example 5 includes the apparatus of any one examples 1-4, further including a surface coating connected to the surface treatment, the surface treatment between the surface coating and the layer of carbide.

Example 6 includes the apparatus of any one examples 1-5, further including a polymer connected to the surface treatment.

Example 7 includes the apparatus of any one examples 1-6, wherein the surface treatment is to modify a surface energy of the surface of the carbide.

Example 8 includes an apparatus comprising a substrate, a layer of silicon carbide on the substrate, and at least one of a nitrene or a carbene grafted onto a surface of the silicon carbide.

Example 9 includes the apparatus of example 8, further including a surface coating on the silicon carbide, the surface coating covalently bonded to the at least one of the nitrene or the carbene.

Example 10 includes the apparatus of any one examples 8 or 9, further including a polymer connected to the silicon carbide via a covalent bond with the at least one of the nitrene or the carbene.

Example 11 includes the apparatus of any one examples 8-10, wherein the apparatus includes include the nitrene, the nitrene including nitrogen, fluorine, and oxygen.

Example 12 includes a method comprising depositing a layer of carbide onto a substrate, and grafting reactive molecules onto a surface of the carbide, the reactive molecules including at least one of a nitrene or a carbene.

Example 13 includes the method of example 12, wherein the grafting is based on insertion of the reactive molecules between covalent bonds of carbon and hydrogen on the surface of the carbide.

Example 14 includes the method of any one examples 12 or 13, further including adding a functional group to the reactive molecules through a derivatization process.

Example 15 includes the method of any one examples 12-14, wherein the grafting includes depositing a solution on to the surface of the carbide through at least one of a spin coating process or a drop casting process, and applying at least one of heat or light to the deposited solution, the at least one of the heat or the light to produce the reactive molecules from the solution.

Example 16 includes the method of example 15, wherein the solution includes an aryl azide.

Example 17 includes the method of any one examples 12-16, further including depositing a photoresist on the carbide, the reactive molecules at an interface of the photoresist and the carbide.

Example 18 includes the method of example 17, wherein the carbide serves as an underlayer for an extreme ultraviolet lithography process.

Example 19 includes the method of any one examples 12-18, wherein the reactive molecules are grafted onto a first portion of the surface of the carbide, a second portion of the surface of the carbide to remain spaced apart from the reactive molecules after the grafting.

Example 20 includes the method of any one examples 12-19, wherein the reactive molecules are grafted directly onto the surface of the carbide without a pre-functionalization of the surface through oxidation.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus comprising:
a semiconductor substrate;
a layer of carbide on the substrate; and
a surface treatment covalently bonded to a surface of the carbide, the surface treatment including at least one of nitrogen or carbon.

2. The apparatus of claim 1, wherein the carbide is silicon carbide.

3. The apparatus of claim 1, wherein the surface treatment includes a nitrene.

4. The apparatus of claim 1, wherein the surface treatment includes a carbene.

5. The apparatus of claim 1, further including a surface coating connected to the surface treatment, the surface treatment between the surface coating and the layer of carbide.

6. The apparatus of claim 1, further including a polymer connected to the surface treatment.

7. The apparatus of claim 1, wherein the surface treatment is to modify a surface energy of the surface of the carbide.

8. An apparatus comprising:
a substrate;
a layer of silicon carbide on the substrate; and
at least one of a nitrene or a carbene grafted onto a surface of the silicon carbide.

9. The apparatus of claim 8, further including a surface coating on the silicon carbide, the surface coating covalently bonded to the at least one of the nitrene or the carbene.

10. The apparatus of claim 8, further including a polymer connected to the silicon carbide via a covalent bond with the at least one of the nitrene or the carbene.

11. The apparatus of claim 8, wherein the apparatus includes include the nitrene, the nitrene including nitrogen, fluorine, and oxygen.

12. A method comprising:
depositing a layer of carbide onto a substrate; and
grafting reactive molecules onto a surface of the carbide, the reactive molecules including at least one of a nitrene or a carbene.

13. The method of claim 12, wherein the grafting is based on insertion of the reactive molecules between covalent bonds of carbon and hydrogen on the surface of the carbide.

14. The method of claim 12, further including adding a functional group to the reactive molecules through a derivatization process.

15. The method of claim 12, wherein the grafting includes:
depositing a solution on to the surface of the carbide through at least one of a spin coating process or a drop casting process; and
applying at least one of heat or light to the deposited solution, the at least one of the heat or the light to produce the reactive molecules from the solution.

16. The method of claim 15, wherein the solution includes an aryl azide.

17. The method of claim 12, further including depositing a photoresist on the carbide, the reactive molecules at an interface of the photoresist and the carbide.

18. The method of claim 17, wherein the carbide serves as an underlayer for an extreme ultraviolet lithography process.

19. The method of claim 12, wherein the reactive molecules are grafted onto a first portion of the surface of the carbide, a second portion of the surface of the carbide to remain spaced apart from the reactive molecules after the grafting.

20. The method of claim 12, wherein the reactive molecules are grafted directly onto the surface of the carbide without a pre-functionalization of the surface through oxidation.
